(19) United States
(12) Patent Application Publication
(10) Pub. No.: US 2008/0262979 A1
(43) Pub. Date: Oct. 23, 2008

(54) HEATING FACILITY USING TIME-OF-USE ELECTRICITY

(75) Inventor: Malcolm Stuart Metcalfe, West Vancouver (CA)

Correspondence Address: DAVIS WRIGHT TREMAINE, LLP/Seattle, 1201 Third Avenue, Suite 2200, SEATTLE, WA, 98101-3045, US

(73) Assignee: SEMPA POWER SYSTEMS LTD., West Vancouver (CA)

(21) Appl. No.: 11/737,060

(22) Filed: Apr. 18, 2007

(51) Int. Cl. G01R 11/00; F24D 11/00

(52) U.S. Cl. 705/412; 237/81

(57) ABSTRACT

A cost-effective method of heating a space in a facility comprises: (a) determining a cost of electricity from an electricity vendor; (b) when the determined cost of electricity is below an electricity pricing setpoint, obtaining sufficient electricity from the vendor to heat a heatable material such as water above a first temperature setpoint; and (c) when the heatable material has a temperature above the first temperature setpoint and a space requires heating, heating the space using at least some of the heat stored in the heatable material. Such method is particularly cost-effective when using electricity charged at a time-of-use basis.

### FIELD OF THE INVENTION

This invention relates generally to heating a facility, and particularly to heating the facility using electricity charged on a time-of-use basis.

### BACKGROUND OF THE INVENTION

Space heating, domestic hot water and recreation facilities such as swimming pools are some of the largest uses of energy in many facilities. Heating can be accomplished with electricity and/or any of a number of heating fuels. The most common heating fuels are petroleum-based fuels such as heating oil, natural gas, or propane. Most facilities use a petroleum-based fuel for all their heating applications. Fuel costs can comprise a significant part of an energy bill for a facility located in colder climates wherein heating is required throughout the day and through multiple seasons of the year. Petroleum based fuel for heating is generally charged based on a commodity price plus a delivery charge, and does not change dramatically based on consumption during a billing period.

A facility's total non-heating electrical load comprises electricity used by devices and fixtures within the facility. The non-heating electrical load typically fluctuates throughout the day, with the lowest demand at night, and the highest demand in the late afternoon and early evening.

A number of pricing models can be applied by electrical utilities for billing its users. One approach is to charge users for electricity usage based on the time of use. This approach is particularly desirable to utilities as the demand for power is not constant; there are certain hours of each day when demand peaks at levels considerably higher than the remainder of the day. To meet peak power demands, the utility may need to purchase additional energy through wholesale contracts on the spot market, at prices that are considerably higher than the cost of purchasing power at non-peak periods.

Utilities employing such a pricing model install electricity utility meters at the user's facility that record the use of electricity over certain intervals of time. These meters allow the utility to charge different rates depending upon the time of day; the rates charged typically reflect the cost of generating or obtaining the electricity by the utility at each period during the day. The intention of the rates is to encourage users to move applications from peak load periods when the purchase of added electricity by the utility is very expensive, into periods when electricity is in a surplus state, and prices are very low.

A facility can be heated by electricity or by a fuel. For example, a facility can be heated by a furnace burning natural gas. The cost of gas is relatively constant, but can be substantially higher than the cost of electricity at off-peak hours. However, during peak electricity use periods, it can be more cost-effective to heat a facility using gas than by electricity when that electricity is purchased on a time-of-use basis.

### SUMMARY

It is an object of the invention to heat a facility in a cost-effective manner. A particular object of the invention is to heat a facility using electricity charged at a time-of-use basis when it is cost effective to do so.

According to one aspect of the invention, there is provided a method of heating a space in a facility, and a system and computer readable medium for carrying out the method. The method comprises: (a) determining a cost of electricity from an electricity vendor; (b) when the determined cost of electricity is below an electricity pricing setpoint, obtaining sufficient electricity from the vendor to heat a heatable material such as water above a first temperature setpoint; and (c) when the heatable material has a temperature above the first temperature setpoint and a space requires heating, heating the space using at least some of the heat stored in the heatable material.

When the heatable material has a temperature at or below the first temperature setpoint, the space can be heated using an energy source other than electricity from the vendor.

When the heatable material is water, the water can be heated in a tank for providing domestic hot water to the facility. In such case, the first temperature setpoint corresponds to a minimum temperature at which heated water can be used to heat the space while still providing enough heated water to supply domestic hot water needs to the facility. The electricity pricing setpoint can be the cost of obtaining energy to heat the space from an energy source other than electricity from the vendor. The energy source other than electricity can be a fuel selected from the group consisting of heating oil, propane, natural gas and butane. The fuel can be burned to heat air in a furnace and wherein heat from the water is transferred to the air in the furnace via a heat exchanger.

When the monitored cost of electricity is above the electricity pricing setpoint, sufficient electricity can be obtained from the vendor to maintain the heatable material at around a second temperature setpoint that is lower than the first temperature setpoint and above a minimum temperature required to supply domestic hot water needs to the facility.

The fuel can be burned to heat the water to at least a minimum temperature required to supply domestic hot water needs to the facility when the price of fuel is less than the price of electricity.

When the monitored cost of electricity is below the electricity pricing setpoint and the temperature of the heatable material is below the first temperature setpoint, electricity can be used to resistively heat the space.

The system for heating the facility comprises: (a) air supply means for delivering air to a space in the facility; (b) an electrical heater for heating a heatable medium; (c) a heating circuit fluidly coupled to the heatable medium and thermally coupled to the air supply means; (d) a controller encoded with instructions and statements for execution on the controller to carry out a method of heating a space comprising: determining a cost of electricity charged by an electricity vendor; when the determined cost of electricity is below an electricity rate setpoint, obtaining sufficient electricity from the vendor to heat the heatable material above a first temperature setpoint using the heater; and when the heatable material has a temperature above the first temperature setpoint and the space requires heating, transferring heat from the heating circuit to air in the air supply means.

The heatable medium can be water and in such case, the system further comprises a domestic hot water tank for storing heated water. The heating circuit can be fluidly coupled to the tank and can further comprise a pump communicative with the controller and operable to circulate heated water through the heating circuit.

The air supply means can further comprise a forced air furnace with a fan therein and communicative with the controller.

### BRIEF DESCRIPTION OF THE DRAWINGS

FIG. 1 is a schematic block diagram of components of a facility heating system according to one embodiment of the invention.

FIG. 2 is a flowchart of a first series of steps executed by a controller of the heating system to control space heating of a facility.

FIG. 3 is a flowchart of a second series of steps executed by a controller of the heating system to control space heating of a facility.

### DETAILED DESCRIPTION OF EMBODIMENTS OF THE INVENTION

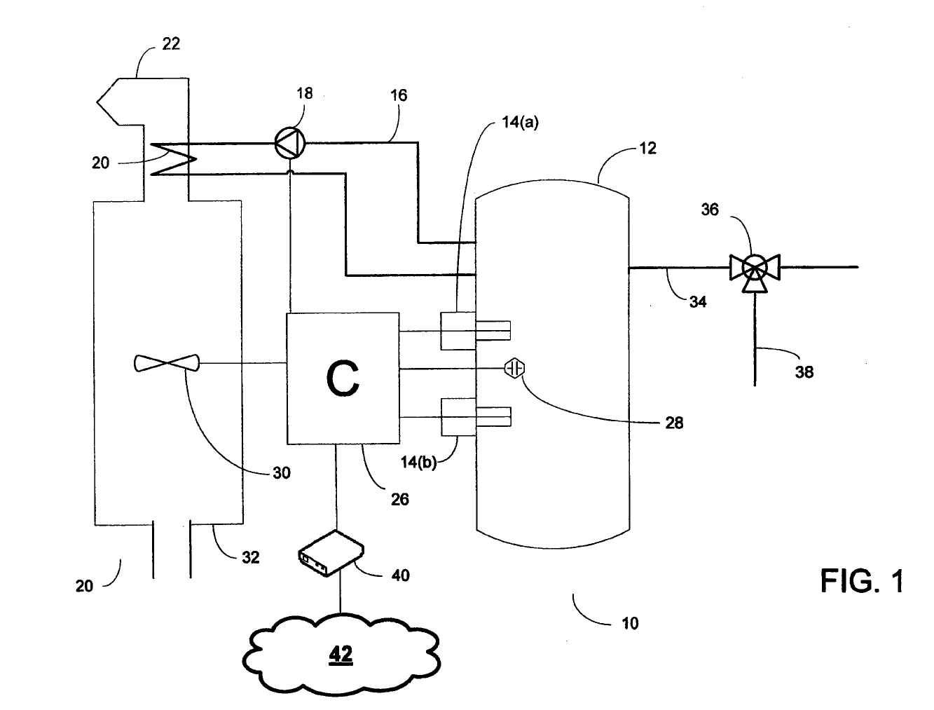

According to one embodiment of the invention and referring to FIG. 1, a facility that uses electricity charged by an electricity vendor on a time-of-use basis is provided with a facility heating system 10 that heats a space in the facility in a cost-effective and efficient manner. As will be explained below, the heating system 10 uses low-cost electricity at off-peak hours to heat water or another heatable material, stores the heat in the water, then uses the stored heat to heat the facility space.

The major components of the facility heating system 10 comprise a hot water tank 12, a pair of electric water heaters 14(a), 14(b) inside the water tank 12, a hot water circuit 16 fluidly coupled to the water tank 12 and having circulation pump 18 and a heating coil 20 thermally coupled to an air supply duct 22 of a forced air heating system 24. A controller 26 is communicative with the water heaters 14(a), 14(b), pump 18, a temperature sensor 28 in the hot water tank 12, and a fan 30 in a furnace 32 of the forced air heating system 24.

At least some of the above components may already be present in the facility, e.g. forced air heating system 24, and hot water tank 12. The system 10 can use such components or separate components can be provided within the scope of this invention. This described embodiment is a heating system 10 which uses an existing forced air heating system 24 and an existing hot water tank 12 used to provide domestic hot water to the facility.

An existing hot water tank 12 that is suitable for use with the heating system 10 is provided with a mixing valve 36 coupled to a hot water discharge pipe 34 from the water tank 12 and to a cold water supply pipe 38 from a cold water source (not shown). The water tank should be insulated to a high standard ensuring that the heat will not escape over a period of several hours. As the temperature of the water in the hot water tank 12 can fluctuate, the mixing valve 36 can be operated to maintain the domestic hot water at a constant maximum domestic hot water temperature setpoint, typically around 120 degrees Fahrenheit. The hot water tank 12 will discharge hot water at or above this temperature set point, and the mixing valve will mix in enough cold water such that the domestic hot water distributed to the facility is maintained at the temperature set point, in a manner that is well known in the art.

The two water heaters 14(a), 14(b) can be the existing heaters in the tank and can be modified to provide the necessary heat output required by the facility heating system 10. Alternatively, one or both of the water heaters 14(a), 14(b) can be installed into the tank 12 to heat the hot water in the tan The size of water tank and the output and number of the heating elements will depend on the space that needs to be heated. For example, to heat a 4,000 square foot space, a 100 gallon hot water tank can be provided with a pair of 6 kW heaters to heat the water in the tank to a maximum elevated temperature setpoint of 190° F. which provides about 70,000 BTU of stored thermal energy.

The hot water circuit 16 is installed to transfer heat from hot water in the tank 12 to air circulated by the forced air heating system 24 to provide space heating for the facility. The hot water circuit 16 is a water loop comprising a water supply pipe extending from the tank 12, a water return pipe extending to the tank 12, and the heating coils 20 having inlet and outlet ends fluidly coupled to the supply and return pipes respectively. The pump 18 is fluidly coupled to the water circuit 16 and is operable to pump heated water from the hot water tank 12 and through the heating coils 20 wherein heat is transferred from the water to the air in the supply duct 22, and to return cooled water back to the tank 12.

The controller 26 monitors the temperature of the water via the temperature sensor 28, which can be the existing thermostat in the tank 12 or via a dedicated sensor, and is also communicative with the facility's space heating thermostat (not shown). The controller 26 can be a direct digital controller (DDC), a PID controller, a programmable logic controller (PLC), an application specific integrated circuit (ASIC), a general purpose computer, or any type of programmable controller as is known in the art.

The controller 26 has a random access memory unit (not shown) that stores data relating to electricity pricing and temperature setpoints for the water tank 12. An input/output device such as an electronic display and keyboard (not shown) is coupled to the controller 30 and can be used to input electricity pricing data and electricity pricing and temperature setpoints into the controller 26. The controller 26 is also coupled to an external communications network to automatically receive and store new electricity pricing data; for example, a modem or network card 40 can be connected to the Internet 42 to automatically update electricity pricing data from an electricity utility or another electricity vendor and to ensure that the time clock in the controller is accurate. The electricity pricing data includes the current market rate of electricity available for purchase by the system 10, priced in units of kilowatthour (kWh). In addition, depending on the jurisdiction, the opportunity may exist to purchase or sell electricity through a power pool or purchase power contracts from an IPP. The electricity pricing data can also include information relating to, but not limited to, current power pool prices at the power pool, such as contracts entered into by the operating environment and current pool prices.

In this embodiment, the controller 26 is programmed with three elevated temperature setpoints for the water in the tank 12. A first setpoint corresponds to the lowest water temperature at which heated water can be circulated through the heating circuit 16 to heat the supply air while still providing enough heated water to supply domestic hot water needs (“minimum space heating temperature setpoint”). A second setpoint corresponds to the target temperature for the water when the price of electricity is below the electricity pricing setpoint (“low cost temperature setpoinf”). A third setpoint corresponds to the target temperature of the water when the price of electricity is above the electricity pricing setpoint (“high cost temperature setpoint”). The high cost temperature setpoint is less than the minimum space heating temperature setpoint, and both are lower than the low cost temperature setpoint.

The electricity pricing setpoint can be set at the discretion of the user, but is preferably set to correspond to a price threshold where it becomes more cost-effective to use electricity to heat the facility than to use another energy source. For example, the cost of heating the facility space using the forced air heating system 24 is the cost of the natural gas burned by the furnace 24. The cost of natural gas tends to be relatively constant, and thus the natural gas pricing set-point may only be manually updated from time to time. Alternatively, the controller 26 can be programmed to obtain natural gas pricing data from the natural gas supplier via the Internet, and adjust the electricity pricing setpoint automatically to correspond to the current natural gas market price.

In a time-of-use electricity jurisdiction, electricity tends to be much cheaper than natural gas in off-peak periods such as evenings and weekends. During peak periods, the cost of electricity can be significantly higher than the cost of natural gas. The controller 26 is programmed to execute a control strategy that uses electricity at off-peak periods (i.e. when electricity is cheaper than natural gas) to maintain the water temperature in the tank 12 at the low cost temperature set point, and to use electricity at peak periods (i.e. when electricity is more expensive than natural gas) to maintain the water temperature in the tank 12 at the high cost temperature set point, wherein the high cost temperature setpoint is lower than the low cost temperature setpoint. When the temperature in the tank is above the minimum space heating temperature setpoint, there is enough thermal energy in the tank to provide for the domestic hot water needs of the facility, and any excess thermal energy is used to heat the supply air in the forced air system to provide space heating for the facility. When the temperature in the tank is below the minimum space heating temperature setpoint, then the furnace is turned on to provide space heating to the facility.

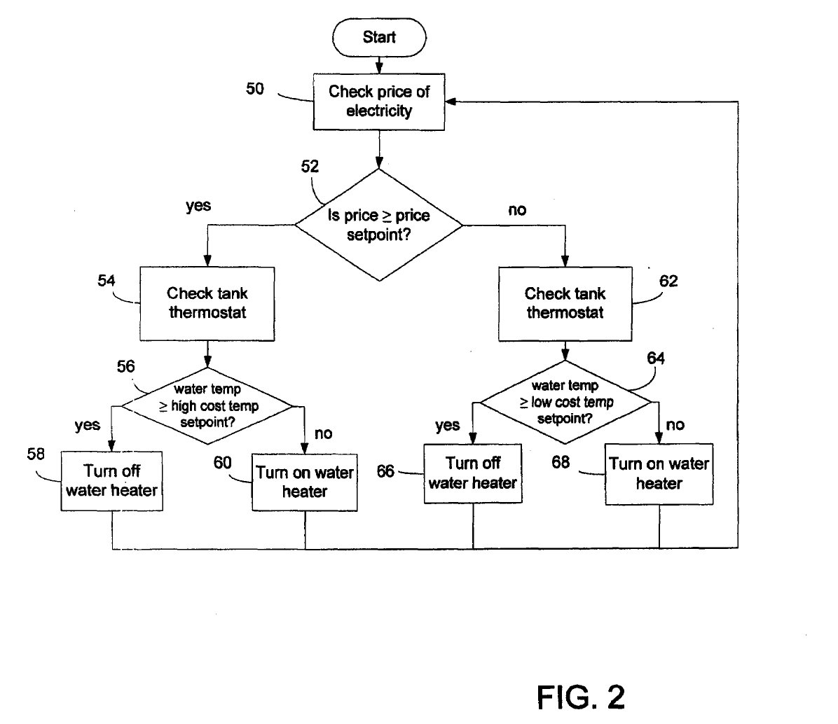

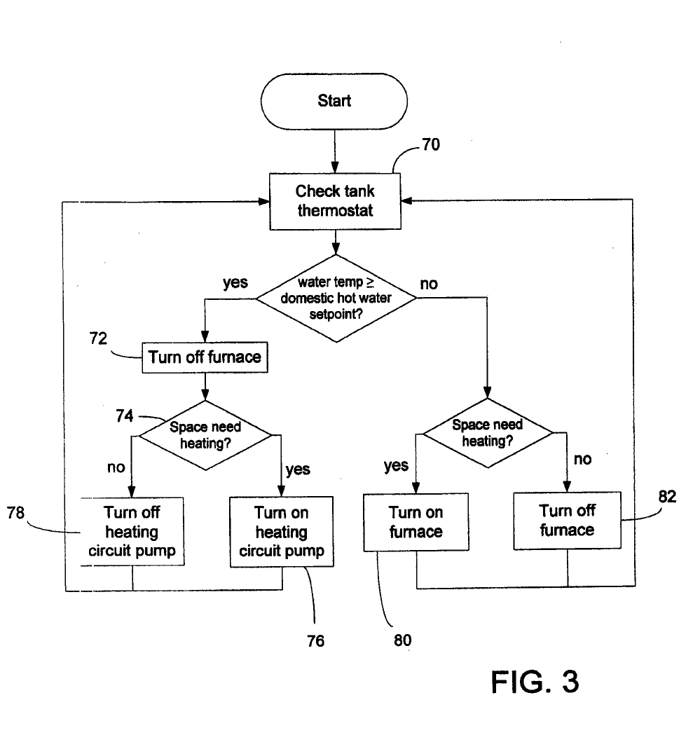

This programmed control strategy is illustrated in the flowcharts shown in FIGS. 2 and 3. Referring to the flowchart in FIG. 2, the controller 26 uses the modem or network card 40 to access the Internet and check the price of electricity (step 50). The controller 26 then compares the price against the electricity pricing setpoint stored in its memory (step 52), and if the price is greater than the setpoint, then the controller 26 enters into a high cost mode wherein the tank water temperature is maintained at the high cost temperature setpoint, i.e. a temperature high enough to provide domestic hot water to the facility but not space heating. In this mode, the controller 26 checks the tank thermostat 28 (step 54) and if the water temperature is at or above the high cost temperature setpoint (step 56), then the water heaters 14(a), 14(b) are turned off if they are not already off (step 58). If the water temperature is below the high cost temperature setpoint, then the water heaters 14(a), 14(b) are turned on if they are not already on (step 60).

If the electricity price is less than the electricity pricing setpoint (step 52), then the controller 26 enters into a low cost mode wherein the tank water temperature is maintained at the low cost temperature setpoint, i.e. the temperature at which the water in the tank stores an selected amount of heat to provide both space heating and domestic hot water to the facility. In this mode, the controller 26 checks the tank thermostat 28 (step 62) and if the water temperature is at or above the low cost temperature setpoint (step 64), then the controller 26 turns off the water heaters 14(a), 14(b) if they are not already off (step 66). If the water temperature is below the low cost temperature setpoint, then the controller 26 turns on the water heaters 14(a), (b) if they are not already on (step 68). Referring now to the flowchart shown in FIG. 3 and simultaneous with the steps carried on in FIG. 2, the controller 26 also monitors the heating requirements of the facility space and operates the furnace 32 or heating circuit 16 as required. The controller 26 first checks water tank thermostat 28 (step 70). If the water temperature is at or higher than the minimum space heating temperature setpoint, then the controller 26 enters into a hot water space heating mode, wherein there is enough heat energy in the water tank to provide both hot water space heating and domestic hot water to the facility. In this mode, the controller 26 turns off the furnace 32 if it is not already off (step 72), then checks the facility space thermostat (step 74). If the space thermostat indicates that the space needs heating, then the controller 26 turns on the heating circuit pump 18 and the furnace fan 30, which causes hot water from the tank 12 to be circulated through the heating circuit 16 and the heating coil 20, and air to be circulated through the air supply duct 22 for heating by the heating coil 20 (step 76). If the space thermometer indicates that the space does not need heating, then the fan 30 and pump 18 are turned off if they are not already off (step 78).

If the water temperature is lower than the minimum space heating temperature setpoint, then the controller enters into a furnace space heating mode, wherein there is not enough heat energy in the tank 12 to provide space heating, and the furnace must be turned on. If the space thermostat indicates that the space needs heating, then the controller turns on the furnace (step 80). The furnace is turned off when the thermostat indicates that the space does not need heating (step 82).

According to an alternative embodiment of the invention, an electrical resistive heater (not shown) is provided in the air supply duct 22 or in the facility space that is coupled to the facility's electrical wiring and communicative with the controller 26. The controller 26 is programmed to activate the resistive heater to provide heat to the supply air when the temperature in the tank 12 falls below the minimum space heating temperature setpoint and when the cost of electricity is less than the electricity pricing setpoint. Under these circumstances, there is not enough heat in the tank 12 to provide space heating but the cost of electricity is less than the cost of natural gas, e.g. when there is significant demand for both domestic hot water and space heating. In such case, it is more cost effective to heat the space using electricity rather than natural gas and the controller 26 will keep the furnace 32 off until it is no longer cost effective to heat using electricity.

According to another alternative embodiment of the invention, the system 10 includes an auxiliary gas boiler (not shown) which heats water by burning a fuel such as natural gas. The gas boiler has feed and supply water lines that are coupled to the hot water tank 12 and can be turned on to heat water when the price of electricity is higher than the price of fuel. The controller 26 programming is modified so that the electric heaters 14(a), 14(b) are kept off so long as the price of electricity is higher than the price of fuel, and the gas boiler is used to maintain the temperature of the tank 12 at least above a temperature required to provide domestic hot water to the facility, or even to provide both domestic hot water and space heating.

According to yet another alternative embodiment, the heating coil 20 of the heating circuit 16 is not thermally coupled to the furnace air supply duct 22 and instead is located in the room(s) of the facility that require space heating. Heat from hot water circulated through the heating circuit 16 is thus radiated directly into the space requiring heating.

### EXAMPLE

A building in Ontario, Canada has a forced air heating system and a domestic hot water tank and was fitted with a heating system as described above. The tank has a 100 gallon capacity and a cold water mixing valve that was calibrated to deliver domestic hot water at 120° F. The controller was programmed with a minimum space heating temperature setpoint of 130° F., a high cost temperature setpoint of 125° F., and a low cost temperature setpoint of 190° F. The tank was fitted with two 6 kW electric water heaters and a heating circuit comprising a pump and hot water piping with heating coils inserted inside the air supply duct of the forced air heating system. The forced air heating system used a natural gas furnace operating at 80% efficiency.

At the time of writing, the cost of natural gas was $13.79/gJ. The controller was programmed with an electricity pricing setpoint of $0.062/kWh, which corresponds approximately to natural gas delivered at $13.79/gJ and takes into account the efficiency of the furnace ($0.062=$13.79/(80%×277.78)). The controller had an Ethernet port which enabled the controller to communicate via the World Wide Web with time-of-use pricing information provided on the Ontario Hydro website. At the time of writing, Ontario Hydro was selling electricity at $0.029/kWh in the evening and on weekends, which is roughly equivalent to natural gas delivered at $8.22/delivered gJ of heat (including efficiencies and taxes). At this price, the controller was programmed to activate the water heaters to heat the water in the water tank to 190° F. setpoint, thereby storing about 70,000 BTU of thermal energy in the tank. When the price of electricity exceeds the cost of electricity setpoint, then the controller stops operation of the water heaters and allows the temperature to fall to the 125° F. setpoint.

When the water temperature in the tank was above the minimum space heating temperature setpoint of 130° F. and the building's space thermostat indicated that space heating was required, the controller stopped operation of the furnace and actuated the furnace fan and the heating circuit pump to deliver heated water to the heating coils, thereby heating the supply air. When the temperature fell below the minimum space heating temperature setpoint of 130° F., the controller stopped the pump operation and activated the furnace.

While the present invention has been described herein by the preferred embodiments, it will be understood by those skilled in the art that various changes may be made and added to the invention. The changes and alternatives are considered within the spirit and scope of the present invention.

What is claimed is:

1. A method of heating a space in a facility, comprising:
(a) determining a cost of electricity from an electricity vendor;
(b) when the determined cost of electricity is below an electricity pricing setpoint, obtaining sufficient electricity from the vendor to heat a heatable material above a first temperature setpoint; and
(c) when the heatable material has a temperature above the first temperature setpoint and a space requires heating, heating the space using at least some of the heat stored in the heatable material.

2. A method as claimed in claim 1 wherein when the heatable material has a temperature at or below the first temperature setpoint, heating the space using an energy source other than electricity from the vendor.

3. A method as claimed in claim 2 wherein the heatable material is water.

4. A method as claimed in claim 3 wherein the water is heated in a tank for providing domestic hot water to the facility and the first temperature setpoint corresponds to a minimum temperature at which heated water can be using to heat the space while still providing enough heated water to supply domestic hot water needs to the facility.

5. A method as claimed in claim 4 wherein the electricity pricing setpoint is the cost of obtaining energy to heat the space from an energy source other than electricity from the vendor.

6. A method as claimed in claim 5 wherein the energy source other than electricity is a fuel selected from the group consisting of heating oil, propane, natural gas and butane.

7. A method as claimed in claim 6 wherein the fuel is burned to heat air in a furnace and wherein heat from the water is transferred to the air in the furnace via a heat exchanger.

8. A method as claimed in claim 4 wherein when the monitored cost of electricity is above the electricity pricing setpoint, obtaining sufficient electricity from the vendor to maintain the heatable material at around a second temperature setpoint that is lower than the first temperature setpoint and above a minimum temperature required to supply domestic hot water needs to the facility.

9. A method as claimed in claim 5 wherein the fuel is burned to heat the water to at least a minimum temperature required to supply domestic hot water needs to the facility when the price of fuel is less than the price of electricity.

10. A method as claimed in claim 1 wherein when the monitored cost of electricity is below the electricity pricing setpoint and the temperature of the heatable material is below the first temperature setpoint, using electricity to resistively heat the space.

11. A computer readable medium encoded with instructions and statements for execution on a controller to carry out a method of heating a space comprising
(a) determining a cost of electricity charged by an electricity vendor;
(b) when the determined cost of electricity is below an electricity rate setpoint, obtaining sufficient electricity from the vendor to heat a heatable material above a first temperature setpoint; and
(c) when the heatable material has a temperature above the first temperature setpoint and a space requires heating, heating the space using at least some of the heat stored in the heatable material.

12. A computer readable medium as claimed in claim 11 the method further comprises heating the space using an energy source other than electricity from the vendor when the heatable material has a temperature at or below the first temperature setpoint.

13. A computer readable medium as claimed in claim 12 wherein the heatable material is water.

14. A computer readable medium as claimed in claim 13 wherein the water is heated in a tank for providing domestic hot water to the facility and the first temperature setpoint corresponds to a minimum temperature at which heated water can be using to heat the space while still providing enough heated water to supply domestic hot water needs to the facility.

15. A computer readable medium as claimed in claim 14 wherein the electricity pricing setpoint is the cost of obtaining energy to heat the space from an energy source other than electricity from the vendor.

16. A computer readable medium as claimed in claim 14 wherein the energy source other than electricity is a fuel selected from the group consisting of heating oil, propane, natural gas and butane.

17. A computer readable medium as claimed in claim 15 wherein the fuel is burned to heat air in a furnace and wherein heat from the water is transferred to the air via a heat exchanger.

18. A computer readable medium as claimed in claim 14 wherein when the monitored cost of electricity is above the electricity pricing setpoint, obtaining sufficient electricity from the vendor to maintain the heatable material at around a second temperature setpoint that is lower than the first temperature setpoint and above a minimum temperature required to supply domestic hot water needs to the facility.

19. A computer readable medium as claimed in claim 15 wherein the fuel is burned to heat the water to at least a minimum temperature required to supply domestic hot water needs to the facility when the price of fuel is less than the price of electricity.

20. A computer readable medium as claimed in claim 11 wherein when the monitored cost of electricity is below the electricity pricing setpoint and the temperature of the heatable material is below the first temperature setpoint, using electricity to resistively heat the space.

21. A system for heating a facility comprising:
(a) air supply means for delivering air to a space in the facility;
(b) an electrical heater for heating a heatable medium;
(c) a heating circuit fluidly coupled to the heatable medium and thermally coupled to the air supply means;
(d) a controller encoded with instructions and statements for execution on a controller to carry out a method of heating a space comprising
determining a cost of electricity charged by an electricity vendor;
when the determined cost of electricity is below an electricity rate setpoint, obtaining sufficient electricity from the vendor to heat the heatable material above a first temperature setpoint using the heater; and
when the heatable material has a temperature above the first temperature setpoint and the space requires heating, transferring heat from the heating circuit to air in the air supply means.

22. A system as claimed in claim 21 wherein the heatable medium is water and the system further comprises a domestic hot water tank for storing heated water.

23. A system as claimed in claim 22 wherein the heating circuit is fluidly coupled to the tank and further comprises a pump communicative with the controller and operable to circulate heated water through the heating circuit.

24. A system as claimed in claim 23 wherein the air supply means further comprises a forced air furnace with a fan therein and communicative with the controller.
